(19) United States
(12) Patent Application Publication
(10) Pub. No.: US 2023/0395407 A1
(43) Pub. Date: Dec. 7, 2023

(54) SUBSTRATE PROCESSING APPARATUS AND SUBSTRATE PROCESSING METHOD

(71) Applicant: Tokyo Electron Limited, Tokyo (JP)

(72) Inventors: Tomofumi EMURA, Kumamoto (JP); Tomotaka OMAGARI, Kumamoto (JP); Tomoo HAYAMA, Kumamoto (JP)

(73) Assignee: Tokyo Electron Limited, Tokyo (JP)

(21) Appl. No.: 18/203,062

(22) Filed: May 30, 2023

(30) Foreign Application Priority Data
Jun. 3, 2022 (JP) 2022-090615

(51) Int. Cl. H01L 21/67

(52) U.S. Cl. CPC H01L 21/67248; H01L 21/67034

(57) ABSTRACT

A substrate processing apparatus includes a processing container that houses a substrate in an internal space thereof, a heating mechanism that heats the internal space from an outside of the internal space, a temperature measurement instrument that measures a temperature of the internal space, and a controller, wherein the controller has a measurement unit that measures a first temperature that is a temperature of the internal space in a case where the heating mechanism is heated at a first setting temperature and a second temperature that is a temperature of the internal space in a case where the heating mechanism is heated at a second setting temperature, and an estimation unit that estimates a setting temperature of the heating mechanism to set a temperature of the internal space at a desired temperature, based on the first setting temperature, the second setting temperature, the first temperature, and the second temperature.

### CROSS-REFERENCE TO RELATED APPLICATION(S)

This application is based upon, and claims the benefit of priority to, Japanese Patent Application No. 2022-090615 filed on Jun. 3, 2022, the entire contents of which are herein incorporated by reference.

### FIELD

A disclosed embodiment(s) relate(s) to a substrate processing apparatus and a substrate processing method.

### BACKGROUND

A substrate processing apparatus has conventionally been known that forms a liquid film for prevention of drying on an upper surface of a substrate such as a semiconductor wafer (that will be called a wafer below) and causes such a substrate with a liquid film that is formed thereon to contact a processing fluid in a supercritical state thereof so as to execute a drying process (see, for example, Japanese Patent Application Publication No. 2013-012538).

### SUMMARY

A substrate processing apparatus according to an embodiment includes a processing container that houses a substrate in an internal space thereof, a heating mechanism that heats the internal space from an outside of the internal space, a temperature measurement instrument that measures a temperature of the internal space, and a controller that controls each unit, wherein the controller has a measurement unit that measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature, and an estimation unit that estimates a setting temperature of the heating mechanism to set a temperature of the internal space that is measured by the temperature measurement instrument at a desired temperature, based on the first setting temperature, the second setting temperature, the first temperature, and the second temperature.

### BRIEF DESCRIPTION OF DRAWING(S)

FIG. 1 is a schematic cross-sectional view where a substrate processing system according to an embodiment is viewed from a top thereof.

FIG. 2 is a schematic cross-sectional view where a substrate processing system according to an embodiment is viewed from a side thereof.

FIG. 3 is a diagram that illustrates a configuration example of a liquid processing unit.

FIG. 4 is a schematic perspective view that illustrates a configuration example of a drying unit.

FIG. 5 is a flowchart that illustrates a procedure of a series of substrate processing that is executed in a substrate processing system according to an embodiment.

FIG. 6 is a cross-sectional view that illustrates a configuration example of a drying unit.

FIG. 7 is a block diagram that illustrates an example of a configuration of a control device according to an embodiment.

FIG. 8 is a diagram that illustrates transition of a chamber temperature in a control process according to an embodiment.

FIG. 9 is a diagram for explaining an estimation process according to an embodiment.

FIG. 10 is a flowchart that illustrates a procedure of a control process that is executed in a substrate processing system according to an embodiment.

### DESCRIPTION OF EMBODIMENT(S)

Hereinafter, an embodiment(s) of a substrate processing apparatus and a substrate processing method as disclosed in the present application will be explained in detail with reference to the accompanying drawing(s). Additionally, the present disclosure is not limited by an embodiment(s) as illustrated below. Furthermore, the drawing(s) is/are schematic where it has to be noted that a relationship between dimensions of respective elements, a ratio of respective elements, etc., may be different from a real one(s). Moreover, parts where a relationship between mutual dimensions and/or a ratio thereof is different may also be included in mutual drawings.

A substrate processing apparatus has conventionally been known that forms a liquid film for prevention of drying on an upper surface of a substrate such as a semiconductor wafer (that will be called a wafer below) and causes such a substrate with a liquid film that is formed thereon to contact a processing fluid in a supercritical state thereof so as to execute a drying process. Such a substrate processing apparatus holds a supercritical fluid at a high pressure in an internal space thereof, so that a processing container thereof is designed so as to be stiff.

On the other hand, in a case where a processing container is designed so as to be stiff, a heat storage capacity of such a processing container is greatly increased, so that a temperature of an internal space does not necessarily coincide with a setting temperature of a heater. Hence, when an internal space is regulated so as to be provided at a desired temperature, a setting temperature of a heater has to be finely regulated repeatedly. That is, in a conventional technique as described above, it takes a very long time to regulate an internal space so as to be provided at a desired temperature.

Accordingly, realization of a technique that overcomes a problem(s) as described above and is capable of executing regulation of a temperature in a processing container efficiently is expected.

Configuration of Substrate Processing System

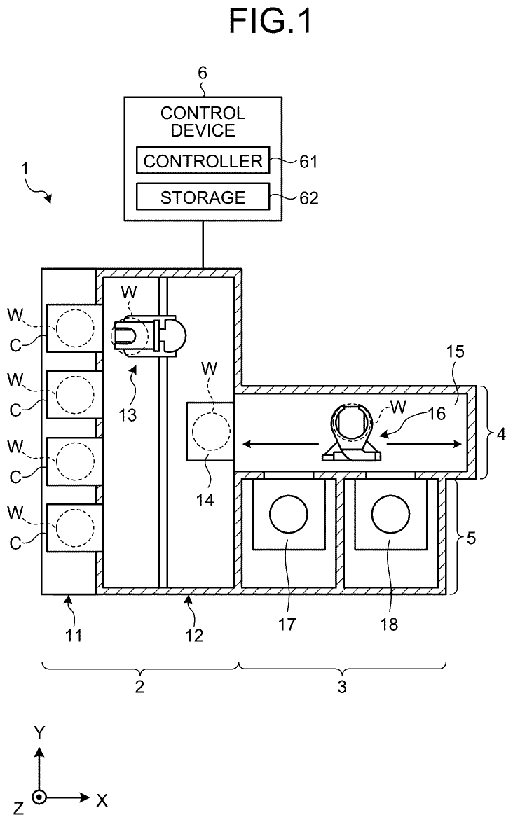

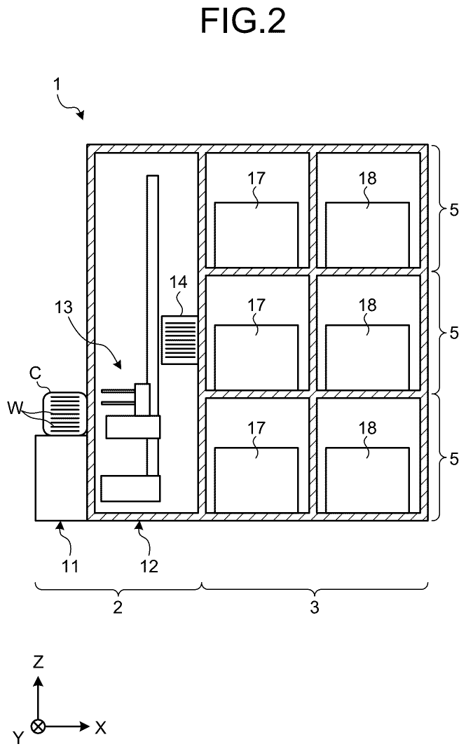

First, a configuration of a substrate processing system 1 (an example of a substrate processing apparatus) according to an embodiment will be explained with reference to FIG. 1 and FIG. 2. FIG. 1 is a schematic cross-sectional view where a substrate processing apparatus 1 according to an embodiment is viewed from a top thereof. Furthermore, FIG. 2 is a schematic cross-sectional view where a substrate processing apparatus 1 according to an embodiment is viewed from a side thereof. Additionally, hereinafter, in order to clarify a positional relationship, an X-axis, a Y-axis, and a Z-axis that are orthogonal to one another are specified and a positive direction of such a Z-axis is provided as a vertically upward direction.

As illustrated in FIG. 1, the substrate processing system 1 includes a carry-in/out station 2 and a processing station 3. The carry-in/out station 2 and the processing station 3 are provided adjacently.

The carry-in/out station 2 includes a carrier placing section 11 and a transfer section 12. A plurality of carriers C that house a plurality of semiconductor wafers W (that will also be described as “wafers W” below) in a horizontal state thereof are placed on the carrier placing section. A wafer W is an example of a substrate.

The transfer section 12 is provided so as to be adjacent to the carrier placing section 11. A transfer device 13 and a delivery unit 14 are arranged in an inside of the transfer section 12.

The transfer device 13 includes a wafer holding mechanism that holds a wafer W. Furthermore, the transfer device 13 is capable of moving in a horizontal direction and a vertical direction and turning around a vertical axis as a center, and executes transfer of a wafer W between a carrier C and the delivery unit 14 by using a wafer holding mechanism.

The processing station 3 is provided so as to be adjacent to the transfer section 12. The processing station 3 includes a transfer block 4 and a plurality of processing blocks 5.

The transfer block 4 includes a transfer area 15 and a transfer device 16. The transfer area 15 is, for example, a cuboidal area that extends along a direction of arrangement of the carry-in/out station 2 and the processing station 3 (a direction of an X-axis). The transfer device 16 is arranged in the transfer area 15.

The transfer device 16 includes a wafer holding mechanism that holds a wafer W. Furthermore, the transfer device 16 is capable of moving in a horizontal direction and a vertical direction and turning around a vertical axis as a center, and executes transfer of a wafer W between the delivery unit 14 and the plurality of processing blocks 5 by using a wafer holding mechanism.

The plurality of processing blocks 5 are arranged so as to be adjacent to the transfer area 15 on one side of the transfer area 15. Specifically, the plurality of processing blocks 5 are arranged on one side of the transfer area 15 (on a side of a negative direction of a Y-axis in the figure(s)) in a direction (a direction of a Y-axis) that is orthogonal to a direction of arrangement of the carry-in/out station 2 and the processing station 3 (a direction of an X-axis).

Furthermore, as illustrated in FIG. 2, the plurality of processing blocks 5 are arranged in multiple stages along a vertical direction. In an embodiment, although a number of a stage(s) of the plurality of processing blocks 5 is three, such a number of a stage(s) of the plurality of processing blocks 5 is not limited to three.

Thus, in the substrate processing system 1 according to an embodiment, the plurality of processing blocks 5 are arranged in multiple stages on one side of the transfer block 4. Then, transfer of a wafer W that is executed between a processing block 5 that is arranged in each stage and the delivery unit 14 is executed by a common transfer device 16 that is arranged in the transfer block 4.

Each processing block 5 includes a liquid processing unit 17 and a drying unit 18. The liquid processing unit 17 executes a process that cleans an upper surface of a wafer W that is a pattern formation surface thereof. Moreover, the liquid processing unit 17 executes a process that forms a liquid film on an upper surface of a wafer W after chemical liquid processing thereof. A configuration of the liquid processing unit 17 will be described later.

The drying unit 18 executes a supercritical drying process for a wafer W after a liquid film formation process. Specifically, the drying unit 18 causes a wafer W after a liquid film formation process to contact a processing fluid in a supercritical state thereof (that will also be called a “supercritical fluid” below) so as to dry such a wafer W.

Additionally, although an example where a supercritical drying process is executed as a process that is executed in the drying unit 18 is illustrated in an embodiment(s) that will be explained below, such a process that is executed in the drying unit 18 is not limited to such a supercritical drying process and may be a process that modifies a wafer W with a supercritical fluid, etc. A configuration of the drying unit 18 will be described later.

Additionally, the substrate processing system 1 has a supply unit that supplies a processing fluid to the drying unit 18 although illustration thereof is not provided in any of FIG. 1 and FIG. 2. Specifically, such a supply unit includes a supply instrument group that includes a flowmeter, a flow controller, a back pressure valve, a heater, etc., and a housing that houses such a supply instrument group. In an embodiment, a supply unit supplies CO₂ as a processing fluid to the drying unit 18.

The liquid processing unit 17 and the drying unit 18 are arranged along the transfer area 15 (that is, along a direction of an X-axis). Among the liquid processing unit 17 and the drying unit 18, the liquid processing unit 17 is arranged at a position that is close to the carry-in/out station 2 and the drying unit 18 is arranged at a position that is distant from the carry-in/out station 2.

Thus, each processing block 5 includes each of the liquid processing unit 17 and the drying unit 18 one by one. That is, the substrate processing system 1 is provided with an identical number of a liquid processing unit(s) 17 and a drying unit(s) 18.

As illustrated in FIG. 1, the substrate processing system 1 includes a control device 6. The control device 6 is, for example, a computer and includes a controller 61 and a storage 62.

The controller 61 includes a microcomputer that has a CPU (Central Processing Unit), a ROM (Read Only Memory), a RAM (Random Access Memory), an input/output port, etc., and/or various types of circuits. A CPU of such a microcomputer reads and executes a program that is stored in a ROM so as to realize control of the transfer devices 13, 16, the liquid processing unit 17, and the drying unit 18, etc.

Additionally, such a program may be stored in a computer-readable storage medium and be installed from such a storage medium to the storage 62 of the control device 6. For a computer-readable storage medium, for example, a hard disk (HD), a flexible disk (FD), a compact disk (CD), a magneto-optical disk (MO), a memory card, etc., are provided.

The storage 62 is realized by, for example, a semiconductor memory element such as a RAM or a flash memory (Flash Memory) or a storage device such as a hard disk or an optical disk. A detail(s) of such a control device 6 will be described later.

Configuration of Liquid Processing Unit

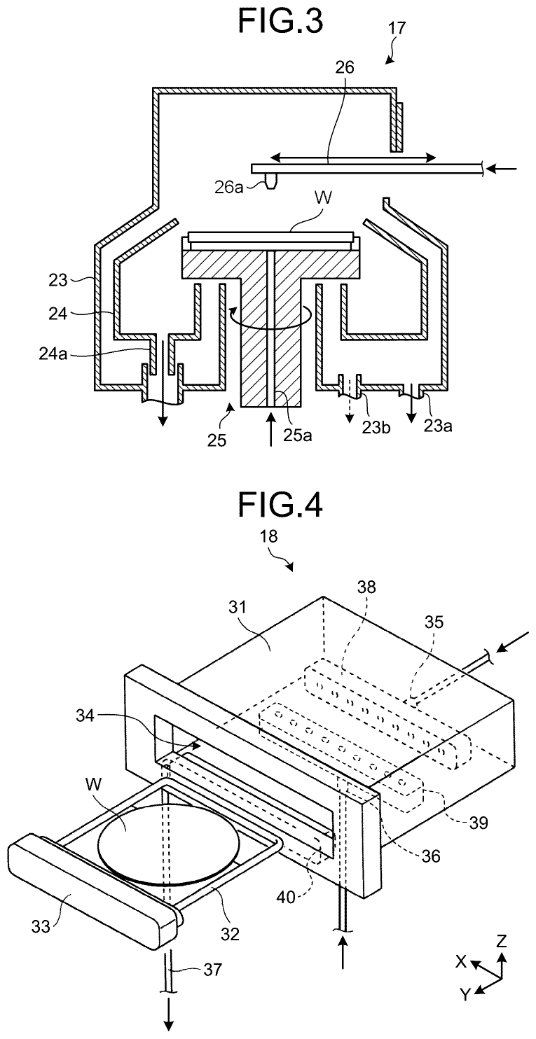

Next, a configuration of a liquid processing unit 17 will be explained with reference to FIG. 3. FIG. 3 is a diagram that illustrates a configuration example of a liquid processing unit 17. For example, the liquid processing unit 17 is configured as a single wafer type cleaning device that cleans a wafer W one by one by spin cleaning.

As illustrated in FIG. 3, the liquid processing unit 17 holds a wafer W substantially horizontally by a wafer holding mechanism 25 that is arranged in an outer chamber 23 that forms a processing space, and rotates such a wafer W by rotating such a wafer holding mechanism 25 around a vertical axis.

Then, the liquid processing unit 17 causes a nozzle arm 26 to move into a space above a rotating wafer W, and supplies a chemical liquid and/or a rinse liquid in a predetermined order from a chemical liquid nozzle 26a that is provided on a distal end part of such a nozzle arm 26, so as to execute a cleaning process for an upper surface of such a wafer W.

Furthermore, a chemical liquid supply route 25a is also formed in an inside of the wafer holding mechanism 25 in the liquid processing unit 17. Then, a lower surface of a wafer W is also cleaned with a chemical liquid and/or a rinse liquid that is/are supplied from such a chemical liquid supply route 25a.

In a cleaning process, for example, elimination of a particle(s) and/or an organic contaminant(s) is first executed by SC1 liquid (a mixed liquid of ammonia and an aqueous solution of hydrogen peroxide) that is an alkaline chemical liquid. Then, rinse cleaning is executed by a deionized water (DeIonized Water: that will also be described as a “DIW” below) that is a rising liquid.

Then, elimination of a natural oxide film is executed by a diluted aqueous solution of hydrofluoric acid (Diluted HydroFluoric acid: that will also be described as a “DHF” below) that is an acidic chemical liquid, and then, rinse cleaning is executed by a DIW.

Various types of chemical liquids as described above are received by the outer chamber 23 and/or an inner cup 24 that is arranged in the outer chamber 23 and are discharged from a drain port 23a that is provided on a bottom part of the outer chamber 23 and/or a drain port 24a that is provided on a bottom part of the inner cup 24. Moreover, an atmosphere in the outer chamber 23 is exhausted from an exhaust port 23b that is provided on a bottom part of the outer chamber 23.

A liquid film formation process is executed after a rinse process in a cleaning process. Specifically, the liquid processing unit 17 supplies IPA in a liquid state thereof (that will also be called an “IPA liquid” below) to an upper surface and a lower surface of a wafer W while the wafer holding mechanism 25 is rotated. Thereby, a DIW that is left on both surfaces of a wafer W is replaced with IPA. Subsequently, the liquid processing unit 17 stops rotation of the wafer holding mechanism 25 gently.

A wafer W where a liquid film formation process is ended is delivered to the transfer device 16 by a non-illustrated delivery mechanism that is provided on the wafer holding mechanism 25 in a state where a liquid film of an IPA liquid is formed on an upper surface thereof, and is carried out of the liquid processing unit 17.

A liquid film that is formed on a wafer W prevents a pattern collapse from being generated by evaporating (vaporizing) of a liquid on an upper surface of a wafer W, during transfer of such a wafer W from the liquid processing unit 17 to the drying unit 18 and/or during an operation of carrying in the drying unit 18.

Outline of Drying Unit

Next, a configuration of a drying unit 18 will be explained with reference to FIG. 4. FIG. 4 is a schematic perspective view that illustrates a configuration example of a drying unit 18.

The drying unit 18 has a housing 31, a holding plate 32, and a lid member 33. The housing 31 is an example of a processing container. An aperture part 34 for carrying in/out of a wafer W is formed on the housing 31. The holding plate 32 holds a wafer W as a processing target in a horizontal direction. The lid member 33 supports such a holding plate 32, and seals the aperture part 34 when a wafer W is carried in the housing 31.

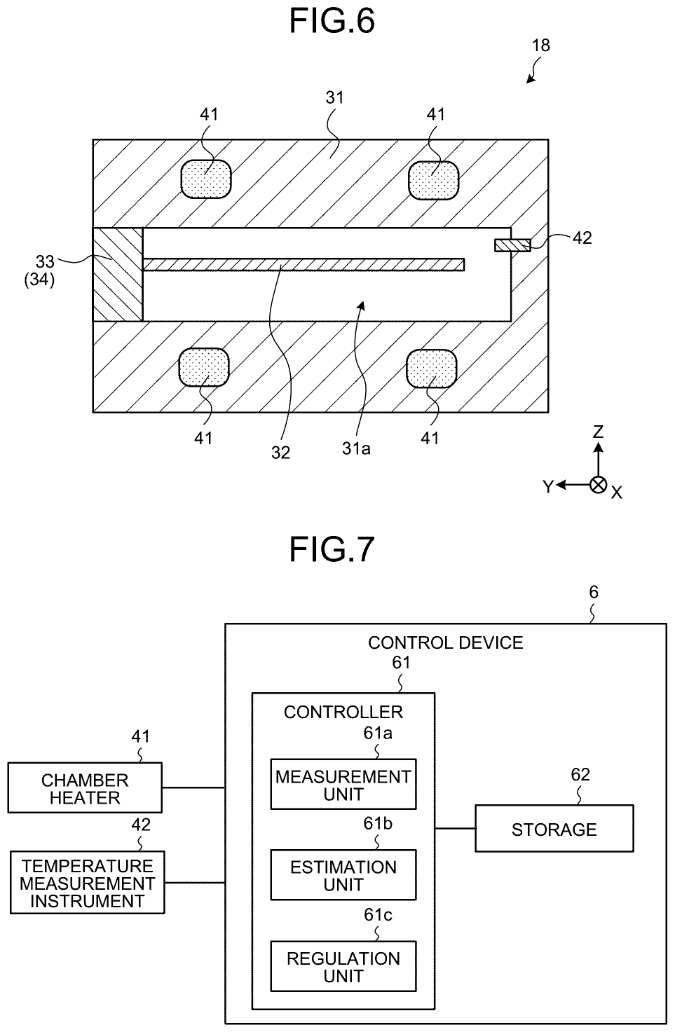

For example, the housing 31 is a container where an internal space 31a (see FIG. 6) that is capable of housing a wafer W with a diameter of 300 (mm) is formed in an inside thereof, and supply ports 35, 36 and a discharge port 37 are provided on a wall part thereof. The supply ports 35, 36 and the discharge port 37 are respectively connected to a supply flow channel and a discharge flow channel for causing a supercritical fluid to flow and pass through the drying unit 18.

A supply port 35 is connected to a side surface of the housing 31 on an opposite side of the aperture part 34. Furthermore, a supply port 36 is connected to a bottom surface of the housing 31. Moreover, the discharge port 37 is connected to a lower side of the aperture part 34. Additionally, although FIG. 4 illustrates two supply ports 35, 36 and one discharge port 37, a number(s) of the supply ports 35, 36 and/or the discharge port 37 is/are not particularly limited.

Furthermore, fluid supply headers 38, 39 and a fluid discharge header 40 are provided in an inside of the housing 31. Then, in the fluid supply headers 38, 39, a plurality of supply ports are formed side by side in a longitudinal direction of such fluid supply headers 38, 39, and in the fluid discharge header 40, a plurality of discharge ports are formed side by side in a longitudinal direction of such a fluid discharge header 40.

A fluid supply header 38 is connected to the supply port 35 and is provided so as to be adjacent to a side surface of the housing 31 on an opposite side of the aperture part 34 in an inside thereof. Furthermore, a plurality of supply ports that are formed side by side on the fluid supply header 38 and are oriented to a side of the aperture part 34.

A fluid supply header 39 is connected to the supply port 36 and is provided at a central part of a bottom surface of the housing 31 in an inside thereof. Furthermore, a plurality of supply ports that are formed side by side on the fluid supply header 39 are oriented upward.

The fluid discharge header 40 is connected to the discharge port 37 and is adjacent to a side surface of the housing 31 on a side of the aperture part 34 in an inside thereof, and is provided below the aperture part 34. Furthermore, a plurality of discharge ports that are formed side by side on the fluid discharge header 40 are oriented upward.

The fluid supply headers 38, 39 supply a supercritical fluid into the housing 31. Furthermore, the fluid discharge header 40 guides and discharges a supercritical fluid in the housing 31 to an outside of the housing 31. Additionally, a supercritical fluid that is discharged to an outside of the housing 31 through the fluid discharge header 40 includes an IPA liquid that is dissolved in a supercritical fluid in a supercritical state thereof from an upper surface of a wafer W.

In such a drying unit 18, an IPA liquid between patterns that are formed on a wafer W contacts a supercritical fluid that is provided in a high-pressure state thereof (for example, 16 (MPa)), so as to be gradually dissolved in a supercritical fluid and be gradually replaced with such a supercritical fluid between such patterns. Then, a space between patterns is ultimately filled with only a supercritical fluid.

Then, after an IPA liquid is eliminated from between patterns, a pressure of an inside of the housing 31 is reduced from a high-pressure state to an atmospheric pressure, so that CO₂ is changed from a supercritical state to a gaseous state and a space between patterns is occupied by only a gas. Thus, an IPA liquid between patterns is eliminated, so that a drying process for a wafer W is completed.

Herein, a supercritical fluid is provided with a viscosity that is less than that of a liquid (for example, an IPA liquid), and also, a high capability to dissolve a liquid, and additionally, no interface is present between a supercritical fluid and a liquid and/or a gas that is/are provided in an equilibrium state thereof. Thereby, in a drying process that uses a supercritical fluid, it is possible to dry a liquid without being influenced by a surface tension thereof. Therefore, according to an embodiment, it is possible to reduce or prevent collapsing of a pattern in a drying process.

Additionally, although an example where an IPA liquid is used as a liquid for prevention of drying and CO₂ in a supercritical state thereof is used as a processing fluid is illustrated in an embodiment, a liquid other than IPA may be used as a liquid for prevention of drying or a fluid other than CO₂ in a supercritical state thereof may be used as a processing fluid.

Substrate Processing Flow

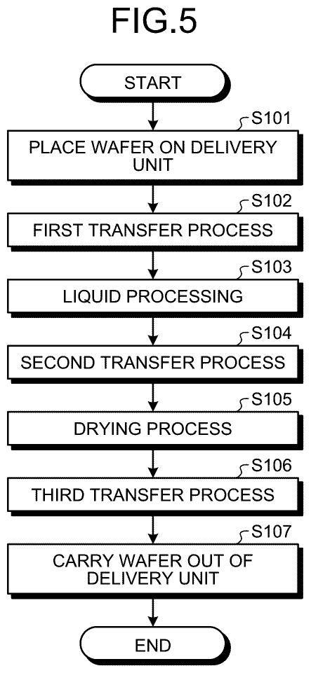

Next, a processing flow for a wafer W in a substrate processing system 1 as described above will be explained with reference to FIG. 5. FIG. 5 is a flowchart that illustrates a procedure of a series of substrate processing that is executed in a substrate processing system 1 according to an embodiment. A series of substrate processing as illustrated in FIG. 5 is executed according to control of a controller 61.

Furthermore, a procedure of a series of substrate processing that are executed for one wafer W is herein illustrated as an example. In the substrate processing system 1, a series of substrate processing as illustrated in FIG. 5 is executed for a plurality of wafers W in parallel.

In the substrate processing system 1, first, a transfer device 13 takes a wafer W from a carrier C and places it on a delivery unit 14 (step S101). Specifically, the transfer device 13 takes a wafer W from a carrier C by using a wafer holding mechanism and places a taken wafer W on the delivery unit 14.

Then, in the substrate processing system 1, a first transfer process is executed (step S102). A first transfer process is a process where a transfer device 16 takes a wafer W from the delivery unit 14 and transfers it to a liquid processing unit 17.

Specifically, the transfer device 16 takes a wafer W from the delivery unit 14 by using a wafer holding mechanism and transfers a taken wafer W to the liquid processing unit 17 of a processing block 5.

Then, in the substrate processing system 1, liquid processing is executed in the liquid processing unit 17 (step S103). Specifically, for example, the liquid processing unit 17 supplies various types of chemical liquids and/or rinse liquids to an upper surface of a wafer W that is a pattern formation surface, so as to eliminate a particle(s), a natural oxide film, etc., from such an upper surface of a wafer W.

Then, for example, the liquid processing unit 17 supplies an IPA liquid to an upper surface of a wafer W after a cleaning process so as to form a liquid film that is provided by such an IPA liquid on such an upper surface of a wafer W.

Then, in the substrate processing system 1, a second transfer process is executed (step S104). Such a second transfer process is a process where the transfer device 16 takes a wafer W with a liquid film that is formed on an upper surface thereof from the liquid processing unit 17 and transfers it to a drying unit 18.

Specifically, the transfer device 16 takes a wafer W from the liquid processing unit 17 by using a wafer holding mechanism and transfers a taken wafer W to a corresponding drying unit 18 of the processing block 5.

Then, in the substrate processing system 1, a drying process is executed in the drying unit 18 (step S105). In such a drying process, the drying unit 18 causes a wafer W with a liquid film that is formed on an upper surface thereof to contact a supercritical fluid so as to dry such a wafer W.

Then, in the substrate processing system 1, a third transfer process is executed (step S106). Such a third transfer process is a process where the transfer device 16 takes a wafer W after a drying process from the drying unit 18 and transfers it to the delivery unit 14.

Specifically, the transfer device 16 takes a wafer W from the drying unit 18 by using a wafer holding mechanism and places a taken wafer W on the delivery unit 14.

Then, in the substrate processing system 1, the transfer device 13 takes a wafer W from the delivery unit 14 and carries it to a carrier C (step S107). Specifically, the transfer device 13 takes a wafer W from the delivery unit 14 by using a wafer holding mechanism and places a taken wafer W on a carrier C. As such a carrying-out process is ended, a series of substrate processing for one wafer W is ended.

Temperature Regulation Mechanism of Drying Unit

Next, a configuration of a temperature regulation mechanism in a drying unit 18 will be explained with reference to FIG. 6. FIG. 6 is a cross-sectional view that illustrates a configuration example of a drying unit 18. Additionally, in FIG. 6, illustration of a fluid supply header 38, a fluid supply header 39, and a fluid discharge header 40, etc., as illustrated in FIG. 4 will be omitted for facilitating understanding thereof.

As described above, an internal space 31a that is capable of housing a wafer W (see FIG. 4) is formed in an inside of a housing 31. Furthermore, in the housing 31, an aperture part 34 for carrying in/out a wafer W is formed so as to be linked to the internal space 31a.

A holding plate 32 holds a wafer W as a processing target in a horizontal direction. A lid member 33 supports such a holding plate 32, and seals the aperture part 34 when a wafer W is carried in the housing 31.

Furthermore, the housing 31 is provided with a chamber heater 41 and a temperature measurement instrument 42. The chamber heater 41 is an example of a heating mechanism and heats the internal space 31a from an outside of the internal space 31a.

For example, a plurality of (four in the figure) chamber heaters 41 are provided so as to surround a periphery of the internal space 31a as illustrated in FIG. 6. Furthermore, the chamber heater 41 is, for example, rod-shaped, and is arranged so as to penetrate through an inside of the housing 31 along a predetermined direction (a direction of an X-axis in the figure).

Additionally, a number and/or arrangement of the chamber heater 41 is not limited to an example in FIG. 6 and any number and/or arrangement may be provided as long as it is possible to heat the internal space 31a.

The temperature measurement instrument 42 measures a temperature of the internal space 31a. For example, the temperature measurement instrument 42 exposes a distal end part thereof to the internal space 31a, so that it is possible to measure a temperature of the internal space 31a. Additionally, arrangement of the temperature measurement instrument 42 is not limited to an example in FIG. 6, and any arrangement is provided as long as it is possible to measure a temperature of the internal space 31a.

Detail of Control Process

Next, a detail(s) of a control process according to an embodiment will be explained with reference to FIG. 7 to FIG. 9. FIG. 7 is a block diagram that illustrates an example of a configuration of a control device 6 according to an embodiment. As illustrated in FIG. 7, the control device 6 includes a controller 61 and a storage 62.

Furthermore, the control device 6 is connected to a chamber heater 41 and a temperature measurement instrument 42 as described above. Additionally, the control device 6 may have various types of functional units that are possessed by a known computer, for example, various types of functional units such as input devices and/or sound output devices, other than functional units as illustrated in FIG. 7.

The storage 62 is realized by, for example, a semiconductor memory element such as a RAM and/or a flash memory or a storage device such as a hard disk and/or an optical disk. The storage 62 stores information that is used for a process in the controller 61.

The controller 61 is realized by, for example, a CPU, an MPU (Micro Processing Unit), a GPU (Graphics Processing Unit), etc., where a program that is stored in the storage 62 is executed while a RAM is provided as a working area.

Furthermore, the controller 61 may be realized by, for example, an integrated circuit such as an ASIC (Application Specific Integrated Circuit) and/or an FPGA (Field Programmable Gate Array).

The controller 61 has a measurement unit 61a, an estimation unit 61b, and a regulation unit 61c, and realizes or executes a function and/or an action of a control process as explained below. Additionally, an internal configuration of the controller 61 is not limited to a configuration as illustrated in FIG. 7 and may be another configuration as long as it is configured to execute a control process as described later.

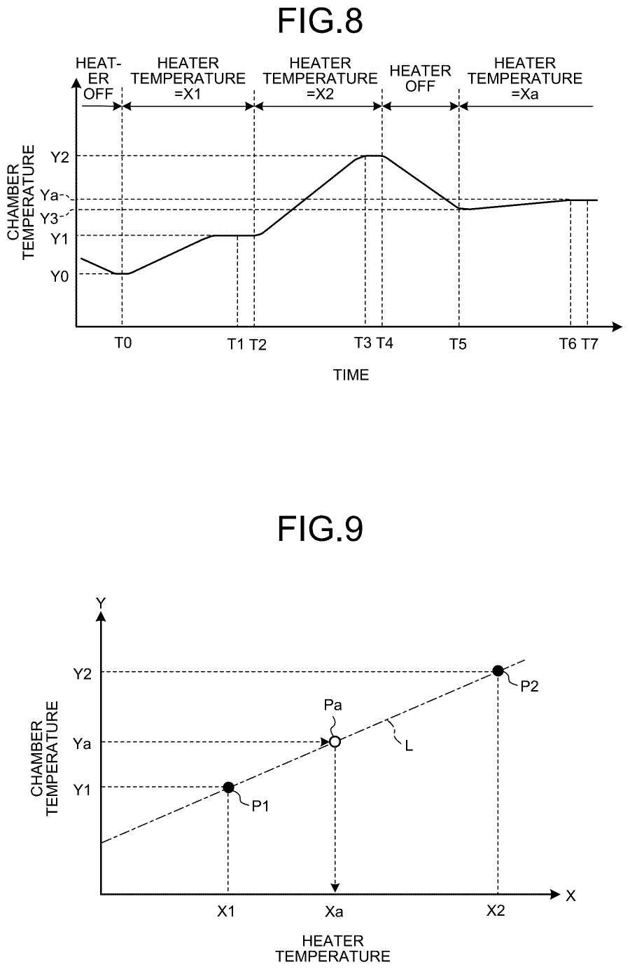

The measurement unit 61a measures temperature data that indicate a correlation between a temperature of an internal space 31a of a housing 31 (that will also be called a chamber temperature below) and a setting temperature of the chamber heater 41 (that will also be called a heater temperature below). A detail(s) of a process that is executed by such a measurement unit 61a will be explained by using FIG. 8.

FIG. 8 is a diagram that illustrates transition of a chamber temperature in a control process according to an embodiment. Additionally, for example, a control process as explained below is executed where an internal space 31 of a housing 31 is provided under an air atmosphere. As illustrated in FIG. 8, a measurement unit 61a first turns off a chamber heater 41 until a chamber temperature is a sufficiently low temperature.

Then, the measurement unit 61a sets a setting temperature of the chamber heater 41 at a temperature X1 at a time TO and operates the chamber heater 41. A temperature X1 is an example of a first setting temperature and is, for example, about 100 (° C.). Accordingly, a chamber temperature is gradually increased from a temperature Y0.

Then, in a case where a heater temperature is a temperature X1, the measurement unit 61a measures a chamber temperature after a time T1 when a time period that is sufficient for such a chamber temperature to reach a steady state (for example, 12 hours) has passed and before a time T2 when a predetermined time period (for example, 1 hour) has further passed.

For example, in an example in FIG. 8, in a case where a heater temperature is a temperature X1, a chamber temperature that reaches a steady state is a temperature Y1. A temperature Y1 is an example of a first temperature.

Then, the measurement unit 61a changes a setting temperature of the chamber heater 41 from a temperature X1 to a temperature X2 at a time T2, and subsequently, operates the chamber heater 41. A temperature X2 is an example of a second setting temperature and is a temperature (for example, about 115 (° C.)) that is higher than a temperature X1. Accordingly, a chamber temperature is gradually increased from a temperature Y1.

Then, in a case where a heater temperature is a temperature X2, the measurement unit 61a measures a chamber temperature after a time T3 when a time period that is sufficient for such a chamber temperature to reach a steady state (for example, 12 hours) has passed and before a time T4 when a predetermined time period (for example, 1 hour) has further passed.

For example, in an example in FIG. 8, in a case where a heater temperature is a temperature X2, a chamber temperature that reaches a steady state is a temperature Y2. A temperature Y2 is an example of a second temperature. Thereby, a measurement process that is executed by the measurement unit 61a is ended.

An explanation for FIG. 7 will be returned to. The estimation unit 61b estimates a setting temperature of the chamber heater 41 for setting a temperature of an internal space 31a at a desired temperature, based on temperature data that indicate a correlation between a chamber temperature and a heater temperature that are measured by the measurement unit 61a as described above. A detail(s) of a process that is executed by such an estimation unit 61b will be explained by using FIG. 9.

FIG. 9 is a diagram for explaining an estimation process according to an embodiment and is a diagram that illustrates a correlation between a heater temperature and a chamber temperature. In an embodiment, an estimation unit 61b plots a chamber temperature (a temperature Y1) in a case where a heater temperature is a temperature X1, on an XY coordinates (a point P1), as illustrated in FIG. 9.

Furthermore, the estimation unit 61b plots a chamber temperature (a temperature Y2) in a case where a heater temperature is a temperature X2, on XY coordinates (a point P2).

Herein, in an embodiment, a supercritical fluid at a high pressure is held in an internal space 31a, so that a housing 31 of a drying unit 18 is designed so as to be stiff. Hence, a heat storage capacity of the housing 31 is greatly increased, so that a heater temperature and a chamber temperature has a linear correlation in the housing 31.

Accordingly, in an embodiment, the estimation unit 61b obtains a straight line L that passes through a point P1 and a point P2 on XY coordinates. A straight line L on XY coordinates is provided by formula (1) as provided below.

X={(X2−X1)/(Y2−Y1)}(Y−Y1)+X1 (1)

Then, the estimation unit 61b inputs a desired chamber temperature (that will also be called a desired temperature Ya below) to such formula (1) so as to estimate a setting temperature Xa of a chamber heater 41 that corresponds to a desired temperature Ya of the internal space 31a.

In other words, the estimation unit 61b obtains a point Pa that is a point of intersection between a straight line L and a straight line Y=Ya and provides a value of X at such a point Pa as a setting temperature Xa of the chamber heater 41 that corresponds to a desired temperature Ya of the internal space 31a, as illustrated in FIG. 9.

Thereby, it is possible to obtain a setting temperature Xa of the chamber heater 41 that corresponds to a desired temperature Ya of the internal space 31 efficiently, without finely regulating a setting temperature of the chamber heater 41 repeatedly. Therefore, according to an embodiment, it is possible to execute regulation of a temperature in the housing 31 efficiently.

Furthermore, in an embodiment, it is preferable to estimate a setting temperature Xa of the chamber heater 41 that corresponds to a desired temperature Ya of the internal space 31, based on a linear function (that is, formula (1)) that is calculated from temperatures X1, X2 that are heater temperatures and temperatures Y1, Y2 that are chamber temperatures. Thereby, it is possible to estimate a setting temperature Xa of the chamber heater 41 accurately and efficiently.

An explanation for FIG. 7 will be returned to. The regulation unit 61c regulates a temperature of the internal space 31a so as to be a desired temperature Ya by using a setting temperature Xa of the chamber heater 41 that is estimated by the estimation unit 61b as described above. A detail(s) of a process that is executed by such a regulation unit 61c will be explained by using FIG. 8.

At a time T4 when a measurement process as described above is ended, the regulation unit 61c turns off the chamber heater 41. Accordingly, a chamber temperature is gradually decreased from a temperature Y2. Furthermore, herein, the estimation unit 61b obtains formula (1) as described above, and further, estimates a setting temperature Xa of the chamber heater 41 that corresponds to a desired temperature Ya of the internal space 31a from such formula (1).

Then, at a time T5 when a temperature Y3 that is a temperature that is lower than a desired temperature Ya is provided, the regulation unit 61c sets a temperature of the chamber heater 41 at a setting temperature Xa and operates the chamber heater 41. Accordingly, a chamber temperature is gradually increased from a temperature Y3, and at a time T6, such a chamber temperature is a desired temperature Ya.

Moreover, the regulation unit 61c measures a chamber temperature until a time T7 when a predetermined time period (for example, 1 hour) has further passed since a time T6, so as to confirm that a chamber temperature is stabilized at a desired temperature Ya, and ends a regulation process.

In an embodiment, as illustrated in FIG. 8, it is preferable to arrange a direction of changing of a temperature between a case where temperatures Y1, Y2 that are chamber temperatures are measured in a measurement process and a case where a chamber temperature is regulated so as to be a desired temperature Ya in a regulation process.

For example, in an example in FIG. 8, the chamber heater 41 is operated so as to reach a temperature Y1 from a temperature that is lower than such a temperature Y1 and such a temperature Y1 is measured, while the chamber heater 41 is operated so as to reach a temperature Y2 from a temperature that is lower than such a temperature Y2 and such a temperature Y2 is measured.

Similarly, in an example in FIG. 8, the chamber heater 41 is operated so as to reach a desired temperature Ya from a temperature Y3 that is lower than such a desired temperature Ya, so that a temperature of the internal space 31a is regulated so as to be such a desired temperature Ya.

Thus, a direction of changing of a temperature is arranged between a measurement process and a regulation process, so that it is possible to regulate the internal space 31a so as to be provided at a desired temperature Ya more accurately, as compared with a case where a direction of changing of a temperature is not arranged between a measurement process and a regulation process.

Additionally, the present disclosure is not limited to an example in FIG. 8, and a direction of a temperature may be arranged so as to decrease such a temperature between a case where temperatures Y1, Y2 that are chamber temperatures are measured in a measurement process and a case where a chamber temperature is regulated so as to be a desired temperature Ya in a regulation process.

On the other hand, a direction of a temperature is arranged so as to increase such a temperature between a case where temperatures Y1, Y2 that are chamber temperatures are measured in a measurement process and a case where a chamber temperature is regulated so as to be a desired temperature Ya in a regulation process, so that it is possible to start a measurement process from a lower chamber temperature.

Therefore, according to an embodiment, it is possible to start a measurement process more quickly and it is possible to reduce electrical usage of the chamber heater 41.

Furthermore, in an embodiment, in a measurement process that is executed by the measurement unit 61a, it is preferable to, first, heat the chamber heater 41 to a temperature X1, and then, heat the chamber heater 41 to a temperature X2 that is higher than such a temperature X1.

Thereby, it is possible to arrange a direction of a temperature so as to increase such a temperature smoothly between a case where temperatures Y1, Y2 that are chamber temperatures are measured in a measurement process and a case where a chamber temperature is regulated so as to be a desired temperature Ya in a regulation process.

Therefore, according to an embodiment, it is possible to start a measurement process more quickly and it is possible to reduce electrical usage of the chamber heater 41.

Additionally, in a case where a direction of a temperature is arranged so as to decrease such a temperature between a case where temperatures Y1, Y2 that are chamber temperatures are measured in a measurement process and a case where a chamber temperature is regulated so as to be a desired temperature Ya in a regulation process, it is preferable that a temperature X2 is lower than a temperature X1.

Thereby, it is possible to arrange a direction of a temperature so as to decrease such a temperature smoothly between a case where temperatures Y1, Y2 that are chamber temperatures are measured in a measurement process and a case where a chamber temperature is regulated so as to be a desired temperature Ya in a regulation process.

Furthermore, although an example where preliminarily set temperatures X1, X2 are used as heater temperatures in a measurement process has been illustrated in an embodiment as described above, the present disclosure is not limited to such an example.

For example, a measurement process may be executed in such a manner that a setting temperature Xa1 that is first estimated after the substrate processing system 1 is installed, etc., is used so as to, first, set a heater temperature at a temperature Xa1−α, and then, set such a heater temperature at a temperature Xa1+α, in a second or later measurement process.

Thereby, in a second or later measurement process, it is possible to position a point Pa as illustrated in FIG. 9 near a midpoint of a point P1 and a point P2, so that it is possible to estimate a setting temperature Xa of the chamber heater 41 more accurately.

Furthermore, in such a case, it is preferable to provide a value of a that is used in a second or later measurement process, within a range of 5 (° C.) to 10 (° C.). Thereby, it is possible to estimate a setting temperature Xa of the chamber heater 41 more accurately.

Furthermore, although an example where waiting is executed until a predetermined time period (for example, 12 hours) has passed when a temperature Y1 (or a temperature Y2) is measured as a chamber temperature has been illustrated in an embodiment as described above, the present disclosure is not limited to such an example.

For example, the measurement unit 61a may measure, as needed, a temperature of the internal space 31a that is measured by the temperature measurement instrument 42, and set a chamber temperature until a time when a predetermined time period (for example, 1 hour) has further passed since a timing when such a chamber temperature reaches a steady state thereof, at a temperature Y1 (or a temperature Y2).

Thereby, it is possible to end a measurement process in a shorter time, so that it is possible to execute regulation of a temperature in the housing 31 more efficiently.

Furthermore, although an example where two points P1, P2 are plotted on XY coordinates in an estimation process by using heater temperatures on two conditions in a measurement process so as to estimate a setting temperature Xa as illustrated in FIG. 8 and FIG. 9 has been illustrated in an embodiment as described above, the present disclosure is not limited to such an example.

For example, in the present disclosure, three or more points may be plotted on XY coordinates in an estimation process by using heater temperatures on three or more conditions in a measurement process so as to estimate a setting temperature Xa. Thereby, it is possible to estimate a setting temperature Xa of the chamber heater 41 more accurately.

Additionally, in such a case, an approximate straight line may be drawn based on three or more points or an approximate curved line may be drawn based on three or more points, instead of a straight line L, on XY coordinates as illustrated in FIG. 9.

Furthermore, although an example where a measurement process that is executed by the measurement unit 61a, an estimation process that is executed by the estimation unit 61b, and a regulation process that is executed by the regulation unit 61c are executed successively has been illustrated in an embodiment as described above, the present disclosure is not limited to such an example.

For example, a measurement process that is executed by the measurement unit 61a and an estimation process that is executed by the estimation unit 61b are preliminarily executed so as to estimate a setting temperature Xa temporarily. Then, when a regulation process is needed separately, such a regulation process may be executed by using a preliminarily estimated setting temperature Xa.

Furthermore, in the present disclosure, a measurement process and an estimation process do not have to be executed each time before a regulation process is executed. A regulation process may be executed by using a previous setting temperature Xa, except immediately after the substrate processing system 1 is installed and/or a case where each unit of the drying unit 18 (for example, the chamber heater 41, the temperature measurement instrument 42, etc.) is replaced.

A substrate processing apparatus (a substrate processing system 1) according to an embodiment includes a processing container (a housing 31), a heating mechanism (a chamber heater 41), a temperature measurement instrument 42, and a controller 61. The processing container (the housing 31) houses a substrate (a wafer W) in an internal space 31a thereof. The heating mechanism (the chamber heater 41) heats the internal space 31a from an outside of the internal space 31a. The temperature measurement instrument 42 measures a temperature of the internal space 31a. The controller 61 controls each unit. Furthermore, the controller 61 has a measurement unit 61a and an estimation unit 61b. The measurement unit 61a measures a first temperature (a temperature Y1) that is a temperature of the internal space 31a that is measured by the temperature measurement instrument 42 in a case where the heating mechanism (the chamber heater 41) is heated at a first setting temperature (a temperature X1). Furthermore, the measurement unit 61a measures a second temperature (a temperature Y2) that is a temperature of the internal space 31a that is measured by the temperature measurement instrument 42 in a case where the heating mechanism (the chamber heater 41) is heated at a second setting temperature (a temperature X2). The estimation unit 61b estimates a setting temperature Xa of the heating mechanism (the chamber heater 41) to set a temperature of the internal space 31a that is measured by the temperature measurement instrument 42 at a desired temperature (a desired temperature Ya), based on the first setting temperature, the second setting temperature, the first temperature, and the second temperature. Thereby, it is possible to execute regulation of a temperature in a housing 31 efficiently.

Furthermore, in the substrate processing apparatus (the substrate processing system 1) according to an embodiment, the estimation unit 61b estimates a setting temperature Xa of the heating mechanism (the chamber heater 41), based on a linear function that is calculated from the first setting temperature, the second setting temperature, the first temperature, and the second temperature. Thereby, it is possible to estimate a setting temperature Xa of a chamber heater 41 accurately and efficiently.

Furthermore, in the substrate processing apparatus (the substrate processing system 1) according to an embodiment, the measurement unit 61a operates the heating mechanism (the chamber heater 41) so as to reach the first temperature (the temperature Y1) from a temperature Y0 that is lower than the first temperature (the temperature Y1) and measures the first temperature (the temperature Y1). Furthermore, the measurement unit 61a operates the heating mechanism (the chamber heater 41) so as to reach the second temperature (the temperature Y2) from a temperature Y1 that is lower than the second temperature (the temperature Y2) and measures the second temperature (the temperature Y2). Thereby, it is possible to start a measurement process more quickly and it is possible to reduce electrical usage of a chamber heater 41.

Furthermore, in the substrate processing apparatus (the substrate processing system 1) according to an embodiment, the measurement unit 61a first heats the heating mechanism (the chamber heater 41) to the first setting temperature (the temperature X1) and measures the first temperature (the temperature Y1). Furthermore, the measurement unit 61a then heats the heating mechanism to the second setting temperature (the temperature X2) that is higher than the first setting temperature (the temperature X1) and measures the second temperature (the temperature Y2). Thereby, it is possible to start a measurement process more quickly and it is possible to reduce electrical usage of a chamber heater 41.

Furthermore, in the substrate processing apparatus (the substrate processing system 1) according to an embodiment, the substrate (the wafer W) is processed with a processing fluid in a supercritical state thereof that is supplied to the internal space 31a, in the processing container (the housing 31). Thereby, a housing 31 is designed so as to be stiff by a supercritical process, so that it is possible to execute regulation of a temperature in such a housing 31 efficiently even in a case where a heat storage capacity of such a housing 31 is very high.

Procedure of Control Process

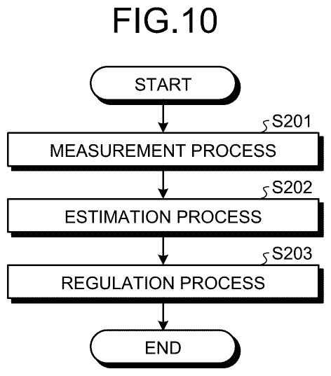

Next, a procedure of a control process according to an embodiment will be explained with reference to FIG. 10. FIG. 10 is a flowchart that illustrates an example of a procedure of a control process that is executed by a substrate processing system 1 according to an embodiment.

In a control process according to an embodiment, first, a controller 61 executes a measurement process (step S201). Specifically, the controller 61 first measures a temperature Y1 of an internal space 31a that is measured by a temperature measurement instrument 42 in a case where a chamber heater 41 is heated at a temperature X1. Then, the controller 61 measures a temperature Y2 of the internal space 31a that is measured by the temperature measurement instrument 42 in a case where the chamber heater 41 is heated at a temperature X2.

Then, the controller 61 estimates a setting temperature Xa of the chamber heater 41 for setting a temperature of the internal space 31a that is measured by the temperature measurement instrument 42 at a desired temperature Ya, based on a temperature X1, a temperature X2, a temperature Y1, and a temperature Y2 (step S202).

Then, the controller 61 sets a temperature of the chamber heater 41 at a setting temperature Xa, so that a temperature of the internal space 31a of the housing 31 is regulated so as to be a desired temperature Ya (step S203), and a series of control processes is ended.

A substrate processing method according to an embodiment includes a measurement step (step S201) and an estimation step (step S202) in a substrate processing system 1 as described above. The measurement step (step S201) measures a first temperature (a temperature Y1) that is a temperature of the internal space 31a that is measured by the temperature measurement instrument 42 in a case where the heating mechanism (the chamber heater 41) is heated at a first setting temperature (a temperature X1). Furthermore, the measurement step (step S201) measures a second temperature (a temperature Y2) that is a temperature of the internal space 31a that is measured by the temperature measurement instrument 42 in a case where the heating mechanism (the chamber heater 41) is heated at a second setting temperature (a temperature X2). The estimation step (step S202) estimates a setting temperature Xa of the heating mechanism to set a temperature of the internal space 31a that is measured by the temperature measurement instrument 42 at a desired temperature (a desired temperature Ya), based on the first setting temperature, the second setting temperature, the first temperature, and the second temperature. Thereby, it is possible to execute regulation of a temperature in a housing 31 efficiently.

Although an embodiment(s) of the present disclosure has/have been explained above, the present disclosure is not limited to an embodiment(s) as described above and a variety of modifications are possible without departing from an essence thereof. For example, although a control process in a drying unit 18 where a wafer W is processed by a supercritical fluid has been illustrated in an embodiment as described above, the present disclosure is not limited to such an example and a technique of the present disclosure may be applied to various types of processing units where another/other process(es) is/are executed.

An embodiment provides a technique that is capable of executing regulation of a temperature in a processing container efficiently.

A substrate processing apparatus according to an aspect of an embodiment includes a processing container, a heating mechanism, a temperature measurement instrument, and a controller. The processing container houses a substrate in an internal space thereof. The heating mechanism heats the internal space from an outside of the internal space. The temperature measurement instrument measures a temperature of the internal space. The controller controls each unit. Furthermore, the controller has a measurement unit and an estimation unit. The measurement unit measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature. The estimation unit estimates a setting temperature of the heating mechanism to set a temperature of the internal space that is measured by the temperature measurement instrument at a desired temperature, based on the first setting temperature, the second setting temperature, the first temperature, and the second temperature.

According to an embodiment, it is possible to execute regulation of a temperature in a processing container efficiently.

Appendix (1): A substrate processing apparatus, including:
a processing container that houses a substrate in an internal space thereof;
a heating mechanism that heats the internal space from an outside of the internal space;
a temperature measurement instrument that measures a temperature of the internal space; and
a controller that controls each unit, wherein
the controller has:
a measurement unit that measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature; and
an estimation unit that estimates a setting temperature of the heating mechanism to set a temperature of the internal space that is measured by the temperature measurement instrument at a desired temperature, based on the first setting temperature, the second setting temperature, the first temperature, and the second temperature.

Appendix (2): The substrate processing apparatus according to Appendix (1), wherein
the estimation unit estimates a setting temperature of the heating mechanism, based on a linear function that is calculated from the first setting temperature, the second setting temperature, the first temperature, and the second temperature.

Appendix (3): The substrate processing apparatus according to Appendix (1) or (2), wherein
the measurement unit operates the heating mechanism to reach the first temperature from a temperature that is lower than the first temperature and measures the first temperature, and operates the heating mechanism to reach the second temperature from a temperature that is lower than the second temperature and measures the second temperature.

Appendix (4): The substrate processing apparatus according to Appendix (1) or (2), wherein
the measurement unit first heats the heating mechanism to the first setting temperature and measures the first temperature, and then heats the heating mechanism to the second setting temperature that is higher than the first setting temperature and measures the second temperature.

Appendix (5): The substrate processing apparatus according to Appendix (1) or (2), wherein
the substrate is processed with a processing fluid in a supercritical state thereof that is supplied to the internal space, in the processing container.

Appendix (6): A substrate processing method, including:
in a substrate processing apparatus that includes a processing container that houses a substrate in an internal space thereof, a heating mechanism that heats the internal space from an outside of the internal space, and a temperature measurement instrument that measures a temperature of the internal space,
a measurement step that measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature; and
an estimation step that estimates a setting temperature of the heating mechanism to set a temperature of the internal space that is measured by the temperature measurement instrument at a desired temperature, based on the first setting temperature, the second setting temperature, the first temperature, and the second temperature.

It should be considered that an embodiment(s) that is/are disclosed herein is/are not limitative but is/are illustrative in all aspects. In fact, it is possible to implement an embodiment(s) as described above in a wide variety of modes thereof. Furthermore, an embodiment(s) as described above may be omitted, substituted, and/or modified in a variety of modes thereof without departing from an appended claim(s) and an essence thereof.

What is claimed is:

1. A substrate processing apparatus, comprising:
a processing container that houses a substrate in an internal space thereof;
a heating mechanism that heats the internal space from an outside of the internal space;
a temperature measurement instrument that measures a temperature of the internal space; and
a controller that controls each unit, wherein
the controller has:
a measurement unit that measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature; and
an estimation unit that estimates a setting temperature of the heating mechanism to set a temperature of the internal space that is measured by the temperature measurement instrument at a desired temperature, based on the first setting temperature, the second setting temperature, the first temperature, and the second temperature.

2. The substrate processing apparatus according to claim 1, wherein
the estimation unit estimates a setting temperature of the heating mechanism, based on a linear function that is calculated from the first setting temperature, the second setting temperature, the first temperature, and the second temperature.

3. The substrate processing apparatus according to claim 1, wherein
the measurement unit operates the heating mechanism to reach the first temperature from a temperature that is lower than the first temperature and measures the first temperature, and operates the heating mechanism to reach the second temperature from a temperature that is lower than the second temperature and measures the second temperature.

4. The substrate processing apparatus according to claim 1, wherein
the measurement unit first heats the heating mechanism to the first setting temperature and measures the first temperature, and then heats the heating mechanism to the second setting temperature that is higher than the first setting temperature and measures the second temperature.

5. The substrate processing apparatus according to claim 1, wherein
the substrate is processed with a processing fluid in a supercritical state thereof that is supplied to the internal space, in the processing container.

6. The substrate processing apparatus according to claim 2, wherein
the measurement unit operates the heating mechanism to reach the first temperature from a temperature that is lower than the first temperature and measures the first temperature, and operates the heating mechanism to reach the second temperature from a temperature that is lower than the second temperature and measures the second temperature.

7. The substrate processing apparatus according to claim 2, wherein
the measurement unit first heats the heating mechanism to the first setting temperature and measures the first temperature, and then heats the heating mechanism to the second setting temperature that is higher than the first setting temperature and measures the second temperature.

8. The substrate processing apparatus according to claim 2, wherein
the substrate is processed with a processing fluid in a supercritical state thereof that is supplied to the internal space, in the processing container.

9. A substrate processing method, including:
in a substrate processing apparatus that comprises a processing container that houses a substrate in an internal space thereof, a heating mechanism that heats the internal space from an outside of the internal space, and a temperature measurement instrument that measures a temperature of the internal space,
a measurement step that measures a first temperature that is a temperature of the internal space that is measured by the temperature measurement instrument in a case where the heating mechanism is heated at a first setting temperature and a second temperature that is a temperature of the internal space that is measured by the temperature measurement instrument in a case where the heating mechanism is heated at a second setting temperature; and
an estimation step that estimates a setting temperature of the heating mechanism to set a temperature of the internal space that is measured by the temperature measurement instrument at a desired temperature, based on the first setting temperature, the second setting temperature, the first temperature, and the second temperature.
